(19) United States
(12) Patent Application Publication
(10) Pub. No.: US 2024/0237201 A1
(43) Pub. Date: Jul. 11, 2024

(54) PRINTED WIRING BOARD

(71) Applicant: IBIDEN CO., LTD., Ogaki (JP)

(72) Inventors: Susumu KAGOHASHI, Ogaki (JP); Maaya TOMIDA, Ogaki (JP)

(73) Assignee: IBIDEN CO., LTD., Ogaki (JP)

(21) Appl. No.: 18/617,671

(22) Filed: Mar. 27, 2024

Related U.S. Application Data
(63) Continuation of application No. 17/822,927, filed on Aug. 29, 2022.

(30) Foreign Application Priority Data
Sep. 8, 2021 (JP) 2021-146430

(51) Int. Cl. H05K 1/02; H05K 1/11

(52) U.S. Cl. CPC H05K 1/0296; H05K 1/115; H05K 2201/0175

(57) ABSTRACT

A printed wiring board includes a first conductor layer, a resin insulating layer formed on the first conductor layer, a second conductor layer formed on a surface of the resin insulating layer and including a signal wiring, and a via conductor formed in the resin insulating layer such that the via conductor is connecting the first conductor layer and the second conductor layer. The resin insulating layer has an opening such that the opening is exposing a portion of the first conductor layer and that the via conductor is formed in the opening of the resin insulating layer, and the resin insulating layer includes inorganic particles and resin such that the resin is forming the surface of the resin insulating layer.

### CROSS-REFERENCE TO RELATED APPLICATIONS

The present application is a continuation of U.S. patent application Ser. No. 17/822,927, filed Aug. 29, 2022, which is based upon and claims the benefit of priority to Japanese Patent Application No. 2021-146430, filed Sep. 8, 2021. The present application claims the benefit of priority to U.S. patent application Ser. No. 17/822,927 and Japanese Patent Application No. 2021-146430. The entire contents of these applications are incorporated herein by reference.

### BACKGROUND OF THE INVENTION

### Field of the Invention

A technology disclosed herein relates to a printed wiring board.

### Description of Background Art

Japanese Patent Application Laid-Open Publication No. 2019-83303 describes a wiring substrate that includes insulating layers for build-up.

### SUMMARY OF THE INVENTION

According to one aspect of the present invention, a printed wiring board includes a first conductor layer, a resin insulating layer formed on the first conductor layer, a second conductor layer formed on a surface of the resin insulating layer and including a signal wiring, and a via conductor formed in the resin insulating layer such that the via conductor is connecting the first conductor layer and the second conductor layer. The resin insulating layer has an opening such that the opening is exposing a portion of the first conductor layer and that the via conductor is formed in the opening of the resin insulating layer, and the resin insulating layer includes inorganic particles and resin such that the resin is forming the surface of the resin insulating layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a printed wiring board according to an embodiment of the present invention;

FIG. 2A is a cross-sectional view schematically illustrating a method for manufacturing a printed wiring board according to an embodiment of the present invention;

FIG. 2B is a cross-sectional view schematically illustrating a method for manufacturing a printed wiring board according to an embodiment of the present invention;

FIG. 2C is a cross-sectional view schematically illustrating a method for manufacturing according to an embodiment of the present invention;

FIG. 2D is a cross-sectional view schematically illustrating a method for manufacturing a printed wiring board according to an embodiment of the present invention;

FIG. 2E is a cross-sectional view schematically illustrating a method for manufacturing a printed wiring board according to an embodiment of the present invention;

FIG. 2F is a cross-sectional view schematically illustrating a method for manufacturing a printed wiring board according to an embodiment of the present invention; and

FIG. 2G is a cross-sectional view schematically illustrating a method for manufacturing a printed wiring board according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### Printed Wiring Board

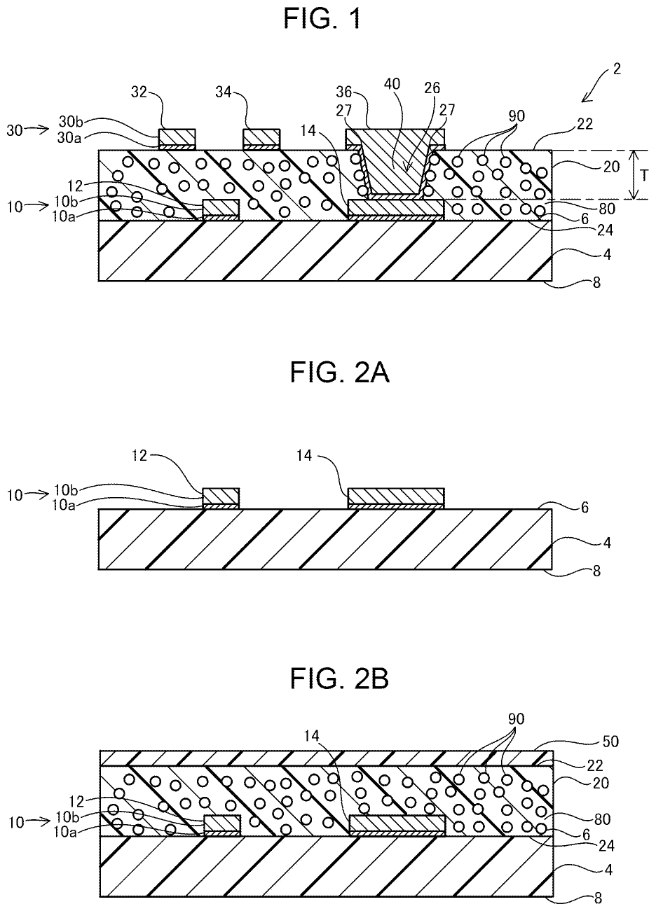

FIG. 1 is a cross-sectional view illustrating a printed wiring board 2 of an embodiment. As illustrated in FIG. 1, the printed wiring board 2 includes an insulating layer 4, a first conductor layer 10, a resin insulating layer 20, a second conductor layer 30, and a via conductor 40.

The insulating layer 4 is formed using a resin. The insulating layer 4 may contain inorganic particles such as silica particles. The insulating layer 4 may contain a reinforcing material such as a glass cloth. The insulating layer 4 has a third surface 6 (upper surface in the drawing) and a fourth surface 8 (lower surface in the drawing) on the opposite side with respect to the third surface 6.

The first conductor layer 10 is formed on the third surface 6 of the insulating layer 4. The first conductor layer 10 includes a signal wiring 12 and a pad 14. Although not illustrated in the drawing, the first conductor layer 10 also includes conductor circuits other than the signal wiring 12 and the pad 14. The first conductor layer 10 is formed of copper. The first conductor layer 10 is formed of a seed layer (10a) and an electrolytic plating film (10b) on the seed layer (10a).

The resin insulating layer 20 is formed on the third surface 6 of the insulating layer 4 and on the first conductor layer 10. The resin insulating layer 20 has a first surface 22 (upper surface in the drawing) and a second surface 24 (lower surface in the drawing) on the opposite side with respect to the first surface 22. An opening 26 exposing the pad 14 is formed in the resin insulating layer 20. The resin insulating layer 20 is formed of a resin 80 and a large number of inorganic particles 90 dispersed in the resin 80. The resin 80 is an epoxy resin. Examples of the resin include a thermosetting resin and a photocurable resin. Examples of the inorganic particles 90 include silica particles and alumina particles.

The first surface 22 of the resin insulating layer 20 is formed only of the resin 80. The inorganic particles 90 are not exposed from the first surface 22. The first surface 22 does not include surfaces of inorganic particles 90. No unevenness is formed on the first surface 22 of the resin insulating layer 20. The first surface 22 is not roughened. The first surface 22 is formed smooth. On the other hand, the inorganic particles 90 are exposed on an inner wall surface 27 of the opening 26. The inner wall surface 27 of the opening 26 includes surfaces of the inorganic particles 90. The inner wall surface 27 of the opening 26 has unevenness. The inner wall surface 27 of the opening 26 is formed of an exposed surface of the resin 80 and exposed surfaces of the inorganic particles 90.

A thickness of the resin insulating layer 20 is two or more times a thickness of the second conductor layer 30. The thickness (T) of the resin insulating layer 20 is a distance between the first surface 22 and the upper surface of the first conductor layer 10.

The second conductor layer 30 is formed on the first surface 22 of the resin insulating layer 20. The second conductor layer 30 includes a first signal wiring 32, a second signal wiring 34, and a land 36. Although not illustrated in the drawing, the second conductor layer 30 also includes conductor circuits other than the first signal wiring 32, the second signal wiring 34, and the land 36. The first signal wiring 32 and the second signal wiring 34 form a pair wiring. The second conductor layer 30 is formed of copper. The second conductor layer 30 is formed of a seed layer (30a) and an electrolytic plating film (30b) on the seed layer (30a).

The via conductor 40 is formed in the opening 26. The via conductor 40 connects the first conductor layer 10 and the second conductor layer 30. In FIG. 1, the via conductor 40 connects the pad 14 and the land 36. The via conductor 40 is formed of the seed layer (30a) and the electrolytic plating film (30b) on the seed layer (30a).

### Method for Manufacturing Printed Wiring Board

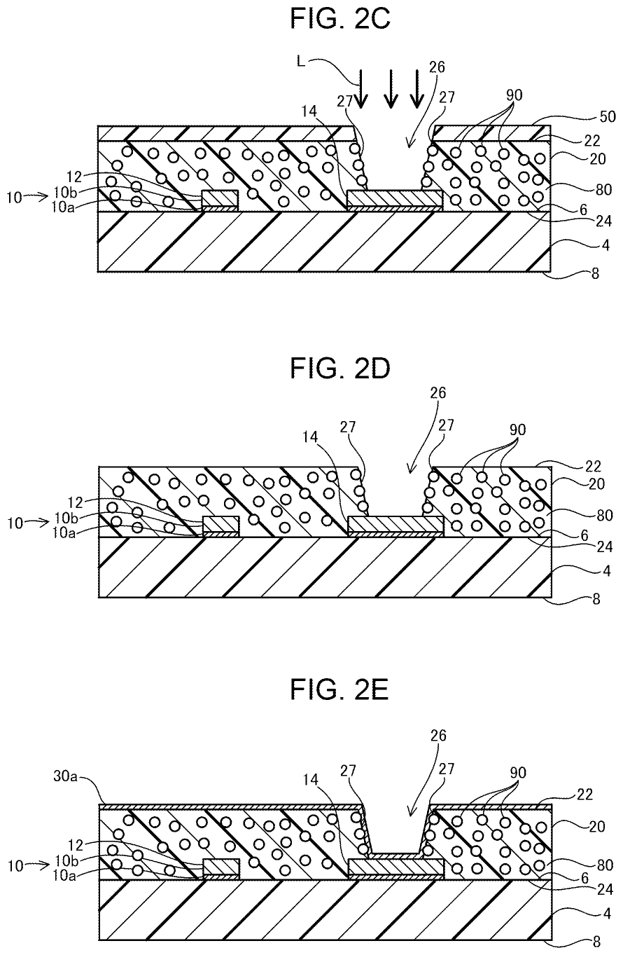

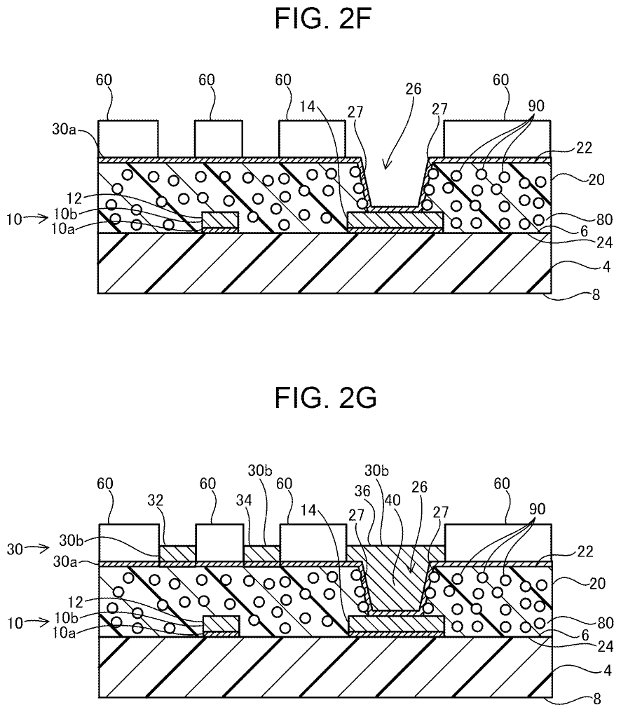

FIGS. 2A-2G illustrate a method for manufacturing the printed wiring board 2 of the embodiment. FIGS. 2A-2G are cross-sectional views. FIG. 2A illustrates the insulating layer 4 and the first conductor layer 10 formed on the third surface 6 of the insulating layer 4. The first conductor layer 10 is formed using a semi-additive method.

As illustrated in FIG. 2B, the resin insulating layer 20 and a protective film 50 are formed on the insulating layer 4 and the first conductor layer 10. The second surface 24 of the resin insulating layer 20 faces the third surface 6 of the insulating layer 4. The protective film 50 is formed on the first surface 22 of the resin insulating layer 20. The first surface 22 of the resin insulating layer 20 is formed only of the resin 80. The inorganic particles 90 are not exposed from the first surface 22. The first surface 22 does not include surfaces of inorganic particles 90. No unevenness is formed on the first surface 22 of the resin insulating layer 20.

The protective film 50 completely covers the first surface 22 of the resin insulating layer 20. An example of the protective film 50 is a film formed of polyethylene terephthalate (PET). A release agent is formed between the protective film 50 and the resin insulating layer 20.

As illustrated in FIG. 2C, laser (L) is irradiated from above the protective film 50. The laser (L) penetrates the protective film 50 and the resin insulating layer 20 at the same time. The opening 26 for a via conductor reaching the pad 14 of the first conductor layer 10 is formed. The laser (L) is, for example, UV laser, or CO₂ laser. The pad 14 is exposed from the opening 26. When the opening 26 is formed, the first surface 22 is covered by the protective film 50. Therefore, when the opening 26 is formed, even when the resin scatters, adherence of the resin to the first surface 22 is suppressed.

After that, the inside of the opening 26 is cleaned. By cleaning the inside of the opening 26, resin residues generated when the opening 26 is formed are removed. The cleaning of the inside of the opening 26 is performed using plasma. That is, the cleaning is performed in a dry process. The cleaning includes a desmear treatment. By the plasma, the resin 80 is selectively removed. The plasma removes the resin 80 faster than the inorganic particles 90. The inner wall surface 27 of the opening 26 is roughened by the plasma.

By cleaning the inside of the opening 26, the inorganic particles 90 are exposed on the inner wall surface 27 of the opening 26 (FIG. 2C). The inner wall surface 27 of the opening 26 includes surfaces of the inorganic particles 90. Unevenness is formed on the inner wall surface 27 of the opening 26. On the other hand, the first surface 22 of the resin insulating layer 20 is covered by the protective film 50. The first surface 22 is not affected by the plasma. The first surface 22 is formed of the resin 80 only. The inorganic particles 90 are not exposed from the first surface 22. The first surface 22 does not include surfaces of inorganic particles 90. No unevenness is formed on the first surface 22 of the resin insulating layer 20. The first surface 22 is formed smooth.

As illustrated in FIG. 2D, the protective film 50 is removed from the resin insulating layer 20. After the protective film 50 is removed, the first surface 22 of the resin insulating layer 20 is not roughened.

As illustrated in FIG. 2E, the seed layer (30a) is formed on the first surface 22 of the resin insulating layer 20. The seed layer (30a) is formed by sputtering. The formation of the seed layer (30a) is performed in a dry process. The seed layer (30a) is also formed on the upper surface of the pad 14 exposed from the opening 26 and on the inner wall surface 27 of the opening 26. The seed layer (30a) is formed of copper.

As illustrated in FIG. 2F, a plating resist 60 is formed on the seed layer (30a). The plating resist 60 has openings for forming the first signal wiring 32, the second signal wiring 34, and the land 36 (FIG. 1).

As illustrated in FIG. 2G, the electrolytic plating film (30b) is formed on the seed layer (30a) exposed from the plating resist 60. The electrolytic plating film (30b) fills the opening 26. The first signal wiring 32, the second signal wiring 34, and the land 36 are formed by the seed layer (30a) and the electrolytic plating film (30b) on the first surface 22. The second conductor layer 30 is formed. The via conductor 40 is formed by the seed layer (30a) and the electrolytic plating film (30b) in the opening 26. The via conductor 40 connects the pad 14 and the land 36. The first signal wiring 32 and the second signal wiring 34 form a pair wiring.

After that, the plating resist 60 is removed. The seed layer (30a) exposed from the electrolytic plating film (30b) is removed. The second conductor layer 30 and the via conductor 40 are formed at the same time. The printed wiring board 2 (FIG. 1) of the embodiment is obtained.

In the printed wiring board 2 (FIG. 1) of the embodiment, the first surface 22 of the resin insulating layer 20 is formed of the resin 80. The inorganic particles 90 are not exposed on the first surface 22. No unevenness is formed on the first surface 22. An increase in standard deviation of the relative permittivity in a portion near the first surface 22 of the resin insulating layer 20 is suppressed. The relative permittivity of the first surface 22 does not greatly vary depending on a location. Even when the first signal wiring 32 and the second signal wiring 34 are in contact with the first surface 22, a difference in propagation speed of an electric signal between the first signal wiring 32 and the second signal wiring 34 can be reduced. Therefore, in the printed wiring board of the embodiment, noise is suppressed. Even when a logic IC is mounted on the printed wiring board 2 of the embodiment, data transmitted via the first signal wiring 32 and data transmitted via the second signal wiring arrive at the logic IC substantially without delay. Malfunction of the logic IC can be suppressed. Even when a length of the first signal wiring 32 and a length of the second signal wiring 34 are 5 mm or more, a difference in propagation speed between the two can be reduced. Even when the length of the first signal wiring 32 and the length of the second signal wiring 34 are 10 mm or more and 20 mm or less, malfunction of the logic IC can be suppressed. A high quality printed wiring board 2 is provided.

In the printed wiring board 2 (FIG. 1) of the embodiment, the thickness (T) of the resin insulating layer 20 is two or more times the thickness of the second conductor layer 30. It is thought that, when the printed wiring board 2 is subjected to heat cycles, a stress applied between the inner wall surface 27 of the opening 26 and the via conductor 40 is greater than a stress applied between the first surface 22 and the second conductor layer 30. Further, the inner wall surface 27 of the opening 26 has unevenness. Therefore, adhesion strength between the inner wall surface 27 of the opening 26 and the via conductor 40 is higher than adhesion strength between the first surface 22 and the second conductor layer 30. The via conductor 40 is unlikely to peel off from the resin insulating layer 20. The second conductor layer 30 is unlikely to peel off from the resin insulating layer 20.

In the printed wiring board 2 of the embodiment, the seed layer (30a) is formed by sputtering (FIG. 2E). Particles forming the seed layer (30a) perpendicularly collide with the first surface 22. Therefore, adhesion strength between the first surface 22 and the seed layer (30a) is high. On the other hand, the particles forming the seed layer (30a) obliquely collide with the inner wall surface 27 of the opening 26. However, the inner wall surface 27 of the opening 26 has unevenness. Therefore, adhesion strength between the seed layer (30a) and the inner wall surface 27 of the opening 26 is high. Even when the first surface 22 does not have unevenness and the inner wall surface 27 of the opening 26 has unevenness, a difference between the adhesion strength between the second conductor layer 30 and the first surface 22 and the adhesion strength between the via conductor 40 and the inner wall surface 27 of the opening 26 can be reduced. A stress is unlikely to concentrate on an interface between the second conductor layer 30 and the first surface 22. A stress is unlikely to concentrate on an interface between the via conductor 40 and the inner wall surface 27 of the opening 26. Even when the printed wiring board 2 is subjected to heat cycles, the via conductor 40 is unlikely to peel off from the resin insulating layer 20. A high quality printed wiring board 2 is provided.

Japanese Patent Application Laid-Open Publication No. 2019-83303 describes a wiring substrate that includes insulating layers for build-up. Examples of the insulating layers for build-up include a first insulating layer and a second insulating layer.

According to Japanese Patent Application Laid-Open Publication No. 2019-83303, insulating particles are dispersed in a thermosetting resin, and the insulating particles include partially exposed particles.

Japanese Patent Application Laid-Open Publication No. 2019-83303 has exposed particles. Therefore, it is thought that an upper surface of the first insulating layer in the patent document is formed of a resin forming the insulating layers for build-up and exposed surfaces of the exposed particles. A first wiring conductor is formed on the upper surface of the first insulating layer. It is thought that there is a difference in relative permittivity between the insulating particles and the resin forming the insulating layers for build-up. It is thought that it is difficult to uniformly disperse the exposed particles. It is thought that it is difficult to make areas of exposed portions of the exposed particles the same. Therefore, it is thought that the relative permittivity of the upper surface of the first insulating layer varies depending on a location. When the first wiring conductor includes two signal wirings, it is thought that there is a large difference in propagation speed between a signal transmitted through one signal wiring and a signal transmitted through the other signal wiring. It is thought that, when a wiring substrate including multiple signal wirings is manufactured using the technology of Patent Document 1, a large amount of noise is generated.

A printed wiring board according to an embodiment of the present invention includes: a first conductor layer; a resin insulating layer that is formed on the first conductor layer, and has a via conductor opening exposing the first conductor layer, a first surface, and a second surface on the opposite side with respect to the first surface; a second conductor layer that is formed on the first surface of the resin insulating layer; and a via conductor that is formed in the opening and connects the first conductor layer and the second conductor layer. The resin insulating layer is formed of inorganic particles and a resin, the second conductor layer includes a signal wiring, and the first surface of the resin insulating layer is formed of the resin.

In a printed wiring board according to an embodiment of the present invention, the first surface of the resin insulating layer is formed of a resin. The first surface of the resin insulating layer is formed only of a resin. The first surface does not include surfaces of inorganic particles. An increase in standard deviation of the relative permittivity in a portion near the first surface of the resin insulating layer is suppressed. The relative permittivity of the first surface of the resin insulating layer is substantially uniform. When the second conductor layer is formed on the first surface, a difference in propagation speed of an electrical signal between signal wirings included in the second conductor layer can be reduced. In the printed wiring board of the embodiment, noise is suppressed.

Obviously, numerous modifications and variations of the present invention are possible in light of the above teachings. It is therefore to be understood that within the scope of the appended claims, the invention may be practiced otherwise than as specifically described herein.

What is claimed is:

1. A method of manufacturing a printed wiring board, comprising:
forming a resin insulating layer on an insulating layer having a first conductor layer formed thereon such that the resin insulating layer covers the first conductor layer;
forming a second conductor layer on a surface of the resin insulating layer such that the second conductor layer includes a signal wiring; and
forming a via conductor in the resin insulating layer such that the via conductor connects the first conductor layer and the second conductor layer,
wherein the forming the resin insulating layer includes forming the resin insulating layer such that the resin insulating layer includes inorganic particles and resin and that the resin forms the surface of the resin insulating layer, and the forming of the second conductor layer and the forming of the via conductor include forming a protective film on the resin insulating layer, forming an opening for the via conductor in the resin insulating layer such that the opening penetrates through the resin insulating layer and the protective film formed on the resin insulating layer and reaches the first conductor layer and that the resin and the inorganic particles form an inner wall surface in the opening, cleaning the opening formed through the resin insulating layer and the protective film such that resin residues are removed from the opening, removing the protective film from the resin insulating layer, forming a seed layer on the surface of the resin insulating layer and the inner wall surface of the resin insulating layer in the opening by sputtering, forming a plating resist on the seed layer such that the plating resist has opening part for the signal wiring, forming an electrolytic plating film on part of the seed layer exposed by the opening part of the plating resist, removing the plating resist from the seed layer, and removing part of the seed layer exposed by the removing of the plating resist.

2. The method of claim 1, wherein the cleaning the opening includes cleaning the opening formed through the protective film and the resin insulating layer such that the surface of the resin insulating layer is covered by the protective film.

3. The method of claim 1, wherein the resin insulating layer is formed such that the surface is consisting of the resin.

4. The method of claim 1, wherein the resin insulating layer is formed such that the surface does not include surfaces of the inorganic particles and is formed of the resin.

5. The method of claim 1, wherein the cleaning the opening includes applying a desmear treatment to the opening formed through the protective film and the resin insulating layer.

6. The method of claim 1, wherein the cleaning the opening includes applying plasma to the opening formed through the protective film and the resin insulating layer.

7. The method of claim 1, wherein the cleaning the opening includes applying plasma to the opening formed through the protective film and the resin insulating layer such that the plasma removes the resin faster than the inorganic particles.

8. The method of claim 1, wherein the cleaning the opening includes applying plasma to the opening formed through the protective film and the resin insulating layer such that the plasma selectively removes the resin.

9. The method of claim 2, wherein the resin insulating layer is formed such that the surface is consisting of the resin.

10. The method of claim 2, wherein the resin insulating layer is formed such that the surface does not include surfaces of the inorganic particles and is consisting of the resin.

11. The method of claim 2, wherein the cleaning the opening includes applying a desmear treatment to the opening formed through the protective film and the resin insulating layer.

12. The method of claim 2, wherein the cleaning the opening includes applying plasma to the opening formed through the protective film and the resin insulating layer.

13. The method of claim 2, wherein the cleaning the opening includes applying plasma to the opening formed through the protective film and the resin insulating layer such that the plasma removes the resin faster than the inorganic particles.

14. The method of claim 2, wherein the cleaning the opening includes applying plasma to the opening formed through the protective film and the resin insulating layer such that the plasma selectively removes the resin.

15. The method of claim 5, wherein the cleaning the opening includes applying plasma to the opening formed through the protective film and the resin insulating layer.

16. The method of claim 5, wherein the cleaning the opening includes applying plasma to the opening formed through the protective film and the resin insulating layer such that the plasma removes the resin faster than the inorganic particles.

17. The method of claim 5, wherein the cleaning the opening includes applying plasma to the opening formed through the protective film and the resin insulating layer such that the plasma selectively removes the resin.

18. The method of claim 11, wherein the cleaning the opening includes applying plasma to the opening formed through the protective film and the resin insulating layer.

19. The method of claim 11, wherein the cleaning the opening includes applying plasma to the opening formed through the protective film and the resin insulating layer such that the plasma removes the resin faster than the inorganic particles.

20. The method of claim 11, wherein the cleaning the opening includes applying plasma to the opening formed through the protective film and the resin insulating layer such that the plasma selectively removes the resin.
